(19) United States
(12) Patent Application Publication
(10) Pub. No.: US 2018/0061862 A1
(43) Pub. Date: Mar. 1, 2018

(54) DISPLAY PANEL AND DISPLAY DEVICE

(71) Applicants: HKC Corporation Limited, Shenzhen (CN); Chongqing HKC Optoelectronics Technology Co., ltd., Chongqing (CN)

(72) Inventor: YU-JEN CHEN, Chongqing (CN)

(21) Appl. No.: 15/804,059

(22) Filed: Nov. 6, 2017

Related U.S. Application Data
(63) Continuation of application No. PCT/CN2017/083793, filed on May 10, 2017.

(30) Foreign Application Priority Data
Dec. 9, 2016 (CN) 201611126505.8

(51) Int. Cl. H01L 27/12

(52) U.S. Cl. CPC H01L 27/124; G02F 1/136286

(57) ABSTRACT

A display panel and a display device are provided. The display panel includes a first substrate, and a second substrate. The first substrate includes active switches and conductive wires coupled with the active switches; and in a same direction, the active switch corresponding to an Nth conductive wire and the active switch corresponding to an (N−1)th conductive wire are adjacent. The active switches above are disposed in a back-to-back manner; the active switch corresponding to the Nth conductive wire and the active switch corresponding to an (N+1)th conductive wire are disposed in a face-to-face manner; a distance between the Nth conductive wire and the (N−1)th conductive wire is smaller than a distance between the Nth conductive wire and the (N+1)th conductive wire. The second substrate is disposed with a light shading layer at positions corresponding to the Nth conductive wire and the (N−1)th conductive wire.

### FIELD OF THE DISCLOSURE

The disclosure relates to a display technical field, and more particularly to a display panel and a display device.

### BACKGROUND

Liquid crystal displays are widely applied due to numerous advantages such as thin bodies, energy saving, radiation-free, etc. Most liquid crystal displays available on the market are backlight-type liquid crystal displays, and such liquid crystal display includes a liquid crystal panel and a backlight module. The working principle of the liquid crystal panel is placing liquid crystal molecules between two parallel glass substrates and loading a driving voltage on the two glass substrates to control rotation directions of the liquid crystal molecules, for refracting rays of the backlight module to generate images.

A thin film transistor-liquid crystal display (TFT-LCD) gradually occupies the dominant position in the display realm at present because of its properties such as low energy consumption, superior image quality and relatively high production yield, etc. Identically, the TFT-LCD includes a liquid crystal panel and a backlight module. The liquid crystal panel includes a color filter (CF) substrate, a thin film transistor (TFT) array substrate and a mask. The opposite internal sides of the substrates have transparent electrodes. A layer of liquid crystal (LC) molecules are interposed between the two substrates.

Light shading members are necessary to be employed for preventing light leakage after the design according to a pixel architecture. A vertical light shading member blocks leaked light of a data line, and a horizontal light-shading member blocks leaked light of a scanning line, but the light shading members will affect the aperture ratio while the light shading members block light. Along with the higher resolution and the smaller pixel areas required by the display panel, the lower aperture ratio will cause the backlight module to provide increasing brightness. The result is consuming electricity and environmentally unfriendly.

### SUMMARY

A technical problem to be solved by the disclosure is to provide a display panel with increased aperture ratio.

Furthermore, the disclosure further provides a display device including the display panel.

An objective of the disclosure is achieved by following embodiments. In particular, a display panel includes a first substrate, and a second substrate.

The first substrate includes a plurality of active switches and conductive wires coupled with the plurality of active switches; and in a same direction, the active switch corresponding to an Nth conductive wire and the active switch corresponding to an (N−1)th conductive wire are adjacent. The active switch corresponding to the Nth conductive wire and the active switch corresponding to the (N−1)th conductive wire are disposed in a back-to-back manner; the active switch corresponding to the Nth conductive wire and the active switch corresponding to an (N+1 )th conductive wire are disposed in a face-to-face manner; a distance between the Nth conductive wire and the (N−1)th conductive wire is shorter than a distance between the Nth conductive wire and the (N+1 )th conductive wire. The second substrate is disposed with a light shading layer at positions corresponding to the Nth conductive wire and the (N−1)th conductive wire.

In an embodiment, the conductive wires include scanning lines coupled with a gate driver of the display panel. The scanning lines are commonly used conductive wires of the display panel and thus are convenient for arrangement and maintenance. The effect is reducing the difficulty in machining as well as the cost.

In an embodiment, the display panel further includes pixel units corresponding to the active switches in a one-to-one manner; the light shading layer forms a plurality of transparent regions along the scanning lines and their intersecting directions. Each of the transparent regions corresponds to two pixel units. Adjacent two scanning lines are disposed close to each other to share a light shading portion extending in the scanning line direction. The transparent regions are significantly enlarged due to the change of disposition of the scanning lines, so that the aperture ratio is increased. The effect is reducing the requirement on the provided brightness of the backlight module and the cost.

In an embodiment, the conductive wires include data lines coupled with a source driver of the display panel. The data lines are commonly used conductive wires of the display panel and thus are convenient for arrangement and maintenance. The effect is reducing the difficulty in machining as well as the cost.

In an embodiment, the display panel further includes pixel units corresponding to the active switches in a one-to-one manner; the light shading layer forms a plurality of transparent regions along the data lines and their intersecting directions. Each of the transparent regions corresponds to two of the pixel units. Adjacent two scanning lines are disposed close to each other to share a light shading portion extending along the data line direction. The transparent regions are significantly improved due to the change of disposition of the data lines, so that the aperture ratio is increased. The effect is reducing the requirement on the provided brightness of the backlight module and the cost.

In an embodiment, the conductive wires include scanning lines coupled with a gate driver of the display panel and data lines coupled with a source driver of the display panel. The scanning lines and the data lines are commonly used conductive wires of the display panel and thus are convenient for arrangement and maintenance. The effect is reducing the difficulty in machining as well as the cost.

In an embodiment, the display panel further includes pixel units corresponding to the active switches in a one-to-one manner; and the light shading layer crisscrosses along directions of the scanning lines and the data lines to thereby form a plurality of transparent regions. Each of the transparent regions corresponds to four of the pixel units. The transparent regions are significantly improved due to the simultaneous alteration of the dispositions of the scanning lines and the data lines, so that the aperture ratio is increased. The effect is reducing the requirement on the provided brightness of the backlight module and the cost.

In an embodiment, the display panel further includes pixel units corresponding to the active switches in a one-to-one manner. The pixel units include a red pixel unit, a green pixel unit and a blue pixel unit. The red pixel unit, the green pixel unit and the blue pixel unit are arranged in sequence along a direction of the conductive wires with same directions. A pixel arrangement manner of RGB strip may be adopted. The pixel arrangement manner of RGB strip is adapted for a design of display panel such as a gate on array (GOA) panel. A pixel arrangement manner of tri-gate can be employed instead with the permission of charging time.

The light shading layer adopts a black matrix. The black matrix is a commonly used light shading material and thus is convenient for manufacturing process and usage.

According to another aspect of the disclosure, the disclosure further provides a display device. The display device includes a backlight module and the display panel as described above.

In a same direction, the active switch corresponding to an Nth conductive wire and the active switch corresponding to an (N−1)th conductive wire are adjacent. The active switch corresponding to the Nth conductive wire and the active switch corresponding to the (N−1)th conductive wire are disposed in a back-to-back manner; the active switch corresponding to the Nth conductive wire and the active switch corresponding to an (N+1 )th conductive wire are disposed in a face-to-face manner; a distance between the Nth conductive wire and the (N−1)th conductive wire is shorter than a distance between the Nth conductive wire and the (N+1 )th conductive wire. Corresponding two adjacent conductive wires are disposed close to each other to share the light shading portion extending in the conductive wire direction, and the above can decrease the coverage area of the light shading layer on the second substrate efficiently, increase the area of the transparent regions and thereby increase the aperture ratio.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a structural schematic view of a first substrate of a display panel according to an embodiment of the disclosure;

FIG. 2 is a structural schematic view of a second substrate of a display panel according to an embodiment of the disclosure;

FIG. 3 is a structural schematic view of a first substrate of a display panel according to an embodiment of the disclosure;

FIG. 4 is a structural schematic view of a second substrate of a display panel according to an embodiment of the disclosure;

FIG. 5 is a structural schematic view of a first substrate of a display panel according to an embodiment of the disclosure;

FIG. 6 is a structural schematic view of a second substrate of a display panel according to an embodiment of the disclosure;

FIG. 7 is a structural schematic view of a first substrate of a display panel according to an embodiment of the disclosure;

FIG. 8 is a structural schematic view of a second substrate of a display panel according to an embodiment of the disclosure;

FIG. 9 is a structural schematic view of a first substrate of a display panel according to an embodiment of the disclosure;

FIG. 10 is a structural schematic view of a second substrate of a display panel according to an embodiment of the disclosure;

FIG. 11 is a structural schematic view of a first substrate of a display panel according to an embodiment of the disclosure; and

FIG. 12 is a structural schematic view of a second substrate of a display panel according to an embodiment of the disclosure.

### DETAILED DESCRIPTION OF PREFERRED EMBODIMENTS

The specific structural and functional details disclosed herein are only representative and are intended for describing exemplary embodiments of the disclosure. However, the disclosure can be embodied in many forms of substitution, and should not be interpreted as merely limited to the embodiments described herein.

In the description of the disclosure, terms such as “center”, “transverse”, “above”, “below”, “left”, “right”, “vertical”, “horizontal”, “top”, “bottom”, “inside”, “outside”, etc. for indicating orientations or positional relationships refer to orientations or positional relationships as shown in the drawings; the terms are for the purpose of illustrating the disclosure and simplifying the description rather than indicating or implying the device or element must have a certain orientation and be structured or operated by the certain orientation, and therefore cannot be regarded as limitation with respect to the disclosure. Moreover, terms such as “first” and “second” are merely for the purpose of illustration and cannot be understood as indicating or implying the relative importance or implicitly indicating the number of the technical feature. Therefore, features defined by “first” and “second” can explicitly or implicitly include one or more the features. In the description of the disclosure, unless otherwise indicated, the meaning of “plural” is two or more than two. In addition, the term “comprise” and any variations thereof are meant to cover a non-exclusive inclusion.

In the description of the disclosure, is should be noted that, unless otherwise clearly stated and limited, terms “mounted”, “connected with” and “connected to” should be understood broadly, for instance, can be a fixed connection, a detachable connection or an integral connection; can be a mechanical connection, can also be an electrical connection; can be a direct connection, can also be an indirect connection by an intermediary, can be an internal communication of two elements. A person skilled in the art can understand concrete meanings of the terms in the disclosure as per specific circumstances.

The terms used herein are only for illustrating concrete embodiments rather than limiting the exemplary embodiments. Unless otherwise indicated in the content, singular forms “a” and “an” also include plural. Moreover, the terms “comprise” and/or “include” define the existence of described features, integers, steps, operations, units and/or components, but do not exclude the existence or addition of one or more other features, integers, steps, operations, units, components and/or combinations thereof.

The disclosure will be further described in detail with reference to accompanying drawings and preferred embodiments as follows.

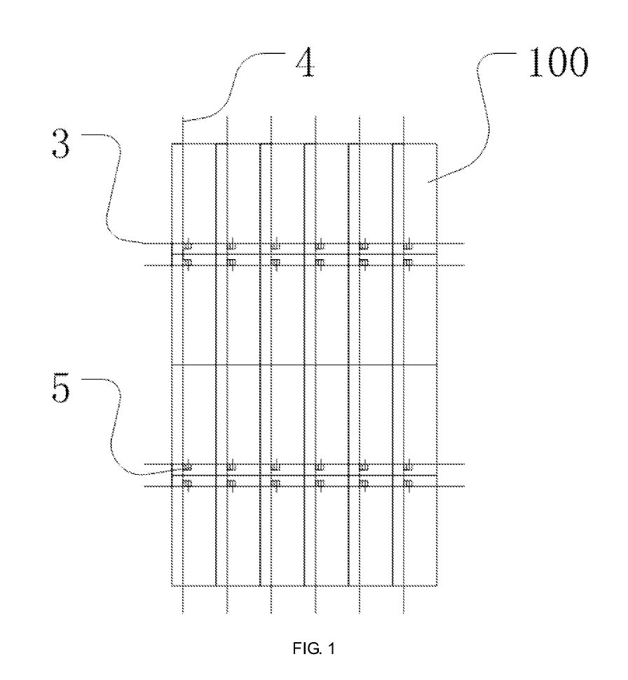

In the following, structures of display panels associated with the disclosure will be described with reference to FIG. 1 through FIG. 12.

The display panel includes a first substrate 100 and a second substrate 200. The first substrate 100 includes multiple active switches 5 and conductive wires coupled with the active switches 5; and in a same direction, the active switch 5 corresponding to an Nth conductive wire and the active switch 5 corresponding to an (N−1)th conductive wire are adjacent. The active switch 5 corresponding to the Nth conductive wire and the active switch 5 corresponding to the (N−1)th conductive wire are disposed contrary (i.e., generally refer to “disposed in a back-to-back manner”); the active switch 5 corresponding to the Nth conductive wire and the active switch 5 corresponding to an (N+1 )th conductive wire are disposed opposite, (i.e., generally refer to “disposed in a face-to-face manner”); a distance between the Nth conductive wire and the (N−1)th conductive wire is shorter than a distance between the Nth conductive wire and the (N+1 )th conductive wire. The second substrate 200 includes a color filter film layer and a light shading layer disposed at positions corresponding to the Nth conductive wire and the (N−1)th conductive wire. Corresponding two adjacent conductive wires are disposed close to each other to share a common light shading portion (e.g., light shading bar) on the conductive wire direction, and the above can decrease the coverage area of the light shading layer on the second substrate efficiently, increase the area of the transparent regions and thereby increase the aperture ratio.

In an embodiment, the conductive wires include first conductive wires and second conductive wires. The first conductive wires and the second conductive wires are intersected with each other. The color filter film layer includes pixels. The first conductive wires and the second conductive wires match with contour curves of the pixels, to thereby ensure pixel electrodes can work normally whatever the shapes of the pixels are.

In an embodiment, the pixels are arranged in an array. Each of the pixels includes pixel units corresponding to different colors. The pixel units can include pixel units corresponding to colors such as white (W), yellow (Y), etc. besides RGB, so that the colors will be more vivid and the display effect will be accordingly better.

In an embodiment, the display panel further includes pixel units corresponding to the active switches 5 in a one-to-one manner. The pixel units can include a red pixel unit 71, a green pixel unit 72, and a blue pixel unit 73. The red pixel unit 71, the green pixel unit 72 and the blue pixel unit 73 are sequentially arranged along a direction of the conductive wires with same directions. A pixel arrangement manner of RGB strip is adopted. The pixel arrangement manner of RGB strip is adapted for a design of display panel such as a gate on array (GOA) panel. Another pixel arrangement manner of tri-gate can be employed instead with the permission of charging time. The pixel units each are disposed to be rectangular.

In an embodiment, the light shading layer adopts a black matrix (BM) 6. The black matrix 6 is a commonly used light-shading material and thus is convenient in both aspects of manufacturing process and usage.

In an embodiment, the active switches 5 can for example adopt thin film transistors.

As another embodiment of the disclosure, the conductive wires include scanning lines 3 coupled with a gate driver of the display panel. The scanning lines 3 are commonly used conductive wires of the display panel and thus are convenient for arrangement and maintenance. The effect is reducing the difficulty in machining as well as the cost. The display panel further includes the pixel units corresponding to the active switches 5 in a one-to-one manner; the light shading layer forms a plurality of transparent regions along the scanning lines 3 and their intersecting directions. Each of the transparent regions corresponds to two pixel units. Adjacent two scanning lines 3 are disposed close to each other to share a common light shading portion (e.g., light shading bar) on the scanning line direction. The transparent regions are significantly improved/increased due to the change of disposition of the scanning lines 3, so that the aperture ratio is increased; the increased aperture ratio reduces the requirement on the provided brightness and the cost.

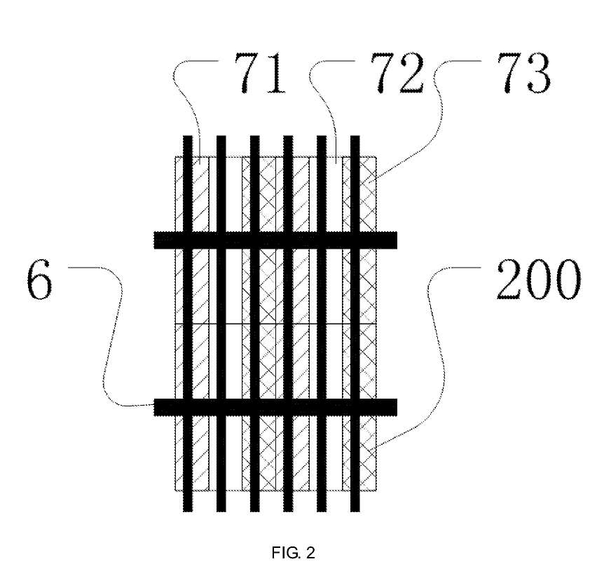

Specifically, FIGS. 1 and 2 show structural schematic views of the display panel of an embodiment of the disclosure. On the first substrate 100, along a vertical conductive wire (may be data line 4) direction, the active switch 5 corresponding to the Nth scanning line 3 and the active switch 5 corresponding to the (N−1)th scanning line 3 are adjacent. The active switch 5 corresponding to the Nth scanning line 3 and the active switch 5 corresponding to the (N−1)th scanning line 3 are disposed in a back-to-back manner; the active switch 5 corresponding to the Nth scanning line 3 and the active switch 5 corresponding to the (N+1 )th scanning line 3 are disposed in a face-to-face manner; a distance between the Nth scanning line 3 and the (N−1)th scanning line 3 is shorter than a distance between the Nth scanning line 3 and the (N+1 )th scanning line 3. Corresponding two adjacent scanning lines 3 are disposed close to each other. On the second substrate 200, the pixel arrangement manner of RGB strip is adopted, the black matrix 6 covers positions corresponding to the scanning lines 3 and the conductive wires on the color filter film layer. The description above is equivalent to two adjacent scanning lines 3 sharing the common light shading portion (e.g., light shading bar as illustrated) on the horizontal direction. As a result, it can decrease the coverage area of the light shading layer on the second substrate 200 efficiently, increase the area of the transparent regions and thereby increase the aperture ratio.

At this moment, the area of the transparent regions is about twice of an area of the transparent regions when the active switches 5 are disposed evenly/uniformly in directions of the scanning lines 3 and the data lines 4.

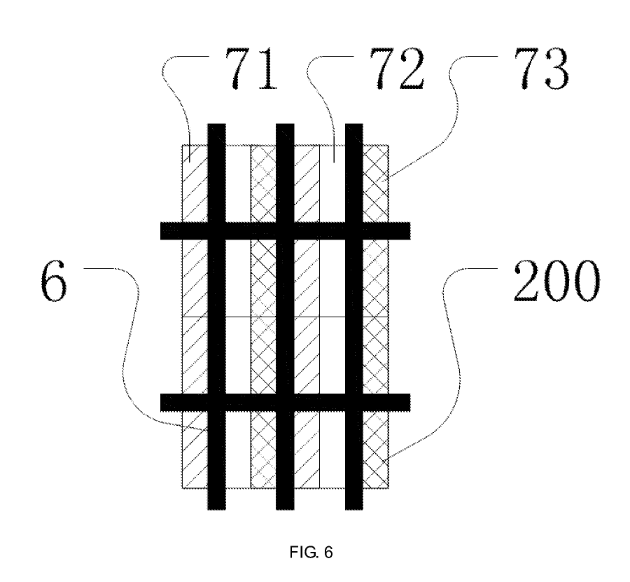

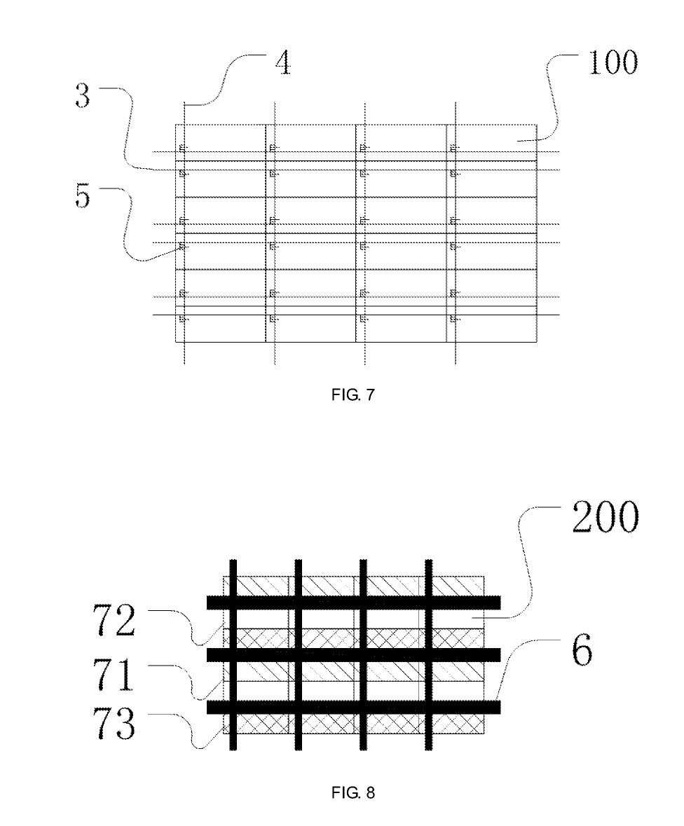

Specifically, FIGS. 7 and 8 show structural schematic views of the display panel according to an embodiment of the disclosure. On the first substrate 100, along a vertical conductive wire (may be data line 4) direction, the active switch 5 corresponding to the Nth scanning line 3 and the active switch 5 corresponding to the (N−1)th scanning line 3 are adjacent. The active switch 5 corresponding to the Nth scanning line 3 and the active switch 5 corresponding to the (N−1)th scanning line 3 are disposed in a back-to-back manner; the active switch 5 corresponding to the Nth scanning line 3 and the active switch 5 corresponding to the (N+1 )th scanning line 3 are disposed in a face-to-face manner; a distance between the Nth scanning line 3 and the (N−1)th scanning line 3 is shorter than a distance between the Nth scanning line 3 and the (N+1 )th scanning line 3. Corresponding two adjacent scanning lines 3 are disposed close to each other. On the second substrate 200, the pixel arrangement manner of tri-gate is employed, the black matrix 6 covers positions corresponding to the scanning lines 3 and the conductive wires on the color filter film layer, the description above is equivalent to two adjacent scanning lines 3 sharing the common light shading portion (e.g., light shading bar as illustrated) in the horizontal direction. As a result, it can decrease the coverage area of the shelter on the second substrate 200 efficiently, increase the area of the transparent regions and thereby increase the aperture ratio.

In this situation, the area of the transparent regions is about twice of the area of the transparent regions when the active switches 5 are disposed evenly in directions of the scanning lines 3 and the data lines 4.

As still another embodiment of the disclosure, the conductive wires include data lines 4 coupled with a source driver of the display panel. The data lines 4 are commonly used conductive wires of the display panel and thus are convenient for arrangement and maintenance. The effect is reducing the difficulty in machining as well as the cost. The display panel further includes the pixel units corresponding to the active switches 5 in a one-to-one manner; the light shading layer forms a plurality of transparent regions along the data lines 4 and their intersecting directions. Each of the transparent regions corresponds to two pixel units. Adjacent two data lines 4 are disposed close to each other to share the common light shading portion (e.g., light shading bar as illustrated) in the data line direction, the transparent regions are significantly improved/enlarged due to the change of disposition of the data lines 4, so that the aperture ratio is increased, and the effect is reducing the requirement on the provided brightness of the backlight module as well as the cost.

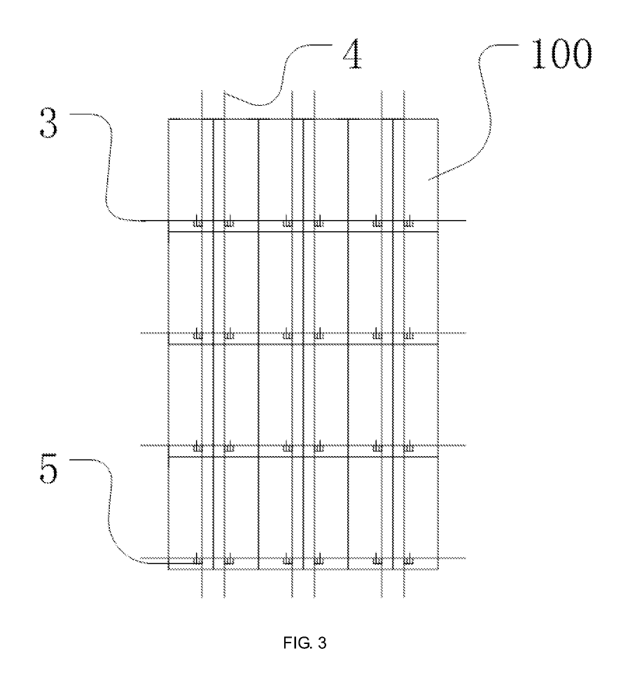

Specifically, as another embodiment of the disclosure, FIGS. 3 and 4 show structural schematic views of the display panel of an embodiment of the disclosure. On the first substrate 100, along a horizontal conductive wire (may be scanning line 3) direction, the active switch 5 corresponding to the Nth data line 4 and the active switch 5 corresponding to the (N−1)th data line 4 are adjacent. The active switch 5 corresponding to the Nth data line 4 and the active switch 5 corresponding to the (N−1)th data line 4 are disposed in a back-to-back manner; the active switch 5 corresponding to the Nth data line 4 and the active switch 5 corresponding to the (N+1 )th data line 4 are disposed in a face-to-face manner; a distance between the Nth data line 4 and the (N−1)th data line 4 is shorter than a distance between the Nth data line 4 and the (N+1 )th data line 4. Corresponding two adjacent data lines 4 are disposed close to each other. On the second substrate 200, the pixel arrangement manner of RGB strip is adopted, the black matrix 6 covers positions corresponding to the conductive wires and the data lines 4 on the color filter film layer, and the description above is equivalent to two adjacent data lines 4 sharing the common light shading portion (e.g., light shading bar as illustrated) in the vertical direction. Consequently, it can decrease the coverage area of the light shading material on the second substrate 200 efficiently, increase the area of the transparent regions and thereby increase the aperture ratio.

In this situation, the area of the transparent regions is about twice of an area of the transparent regions when the active switches 5 are disposed evenly in directions of the scanning lines 3 and the data lines 4.

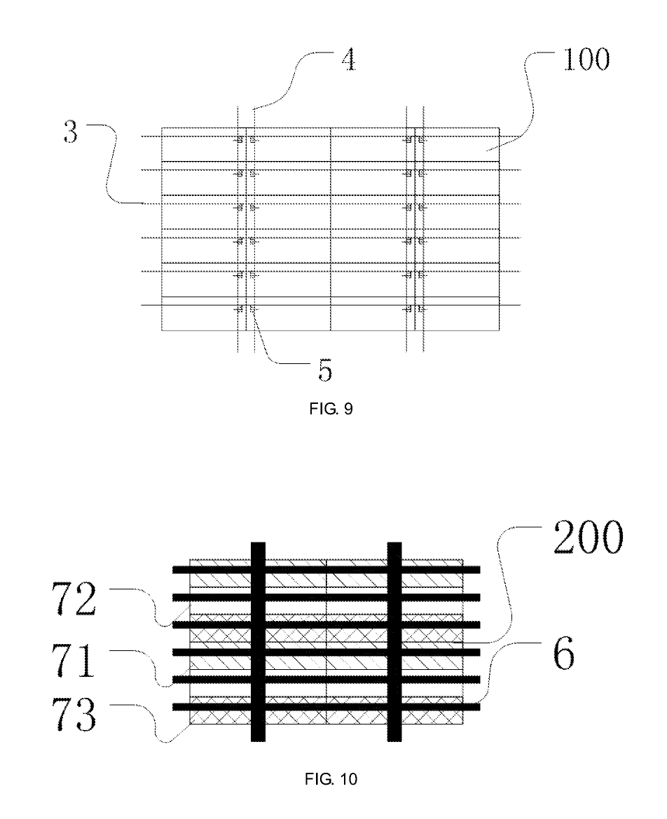

Specifically, as another embodiment of the disclosure, FIGS. 9 and 10 show structural schematic views of the display panel of an embodiment of the disclosure. On the first substrate 100, along a horizontal conductive wire (may be scanning line 3) direction, the active switch 5 corresponding to the Nth data line 4 and the active switch 5 corresponding to the (N−1)th data line 4 are adjacent. The active switch 5 corresponding to the Nth data line 4 and the active switch 5 corresponding to the (N−1)th data line 4 are disposed in a back-to-back manner; the active switch 5 corresponding to the Nth data line 4 and the active switch 5 corresponding to the (N+1 )th data line 4 are disposed in a face-to-face manner; a distance between the Nth data line 4 and the (N−1)th data line 4 is shorter than a distance between the Nth data line 4 and the (N+1 )th data line 4. Corresponding two adjacent data lines 4 are disposed close to each other. On the second substrate 200, the pixel arrangement manner of tri-gate is adopted, the black matrix 6 covers positions corresponding to the conductive wires and the data lines 4 on the color filter film layer, and the description above is equivalent to two adjacent data lines 4 sharing the common light shading portion (e.g., light shading bar as illustrated) in the vertical direction. Consequently, it can decrease the coverage area of the light shading layer on the second substrate 200 efficiently, increase the area of the transparent regions and thereby increase the aperture ratio.

At this moment, the area of the transparent regions is about twice of an area of the transparent regions when the active switches 5 are disposed evenly in directions of the scanning lines 3 and the data lines 4.

As even still another embodiment of the disclosure, the conductive wires include scanning lines 3 coupled with a gate driver of the display panel and data lines 4 coupled with a source driver of the display panel. The scanning lines 3 and the data lines 4 are commonly used conductive wires of the display panel and thus are convenient for arrangement and maintenance, and the effect is reducing the difficulty in machining as well as the cost. The display panel further includes pixel units corresponding to the active switches 5 in a one-to-one manner; and the light shading layer crisscrosses along directions of the scanning lines 3 and the data lines 4 to form a plurality of transparent regions. Each of the transparent regions corresponds to four pixel units. The transparent regions are significantly improved/enlarged due to the simultaneous changes of disposition of the scanning lines 3 and the data lines 4, so that the aperture ratio is increased; the effect is reducing the requirement on the provided brightness of the backlight module and the cost.

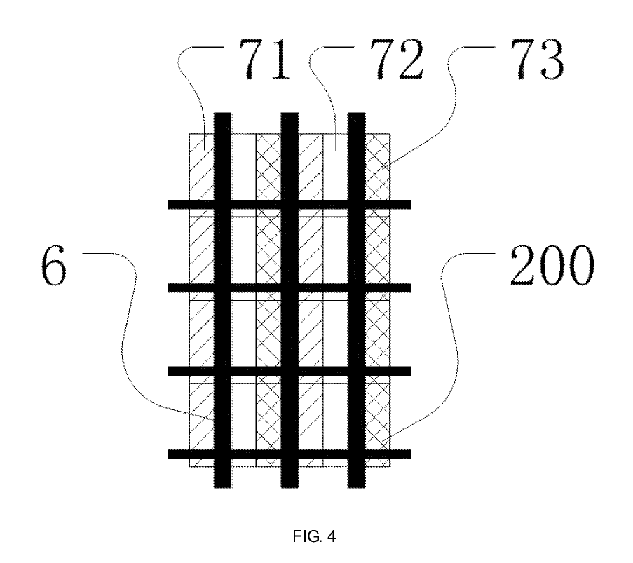

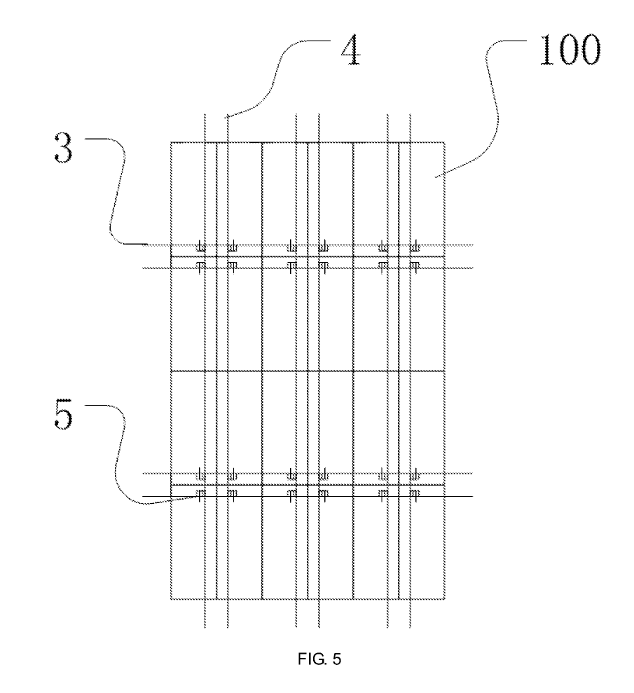

Specifically, FIGS. 5 and 6 show structural schematic views of the display panel of an embodiment of the application. On the first substrate 100, along a vertical data line 4 direction, the active switch 5 corresponding to the Nth scanning line 3 and the active switch 5 corresponding to the (N−1)th scanning line 3 are adjacent. The active switch 5 corresponding to the Nth scanning line 3 and the active switch 5 corresponding to the (N−1)th scanning line 3 are disposed in a back-to-back manner; the active switch 5 corresponding to the Nth scanning line 3 and the active switch 5 corresponding to the (N+1 )th scanning line 3 are disposed in a face-to-face manner; a distance between the Nth scanning line 3 and the (N−1)th scanning line 3 is shorter than a distance between the Nth scanning line 3 and the (N+1 )th scanning line 3, and corresponding two adjacent scanning lines 3 are disposed close to each other. Along a horizontal scanning line 3 direction, the active switch 5 corresponding to the Nth data line 4 and the active switch 5 corresponding to the (N−1)th data line 4 are adjacent. The active switch 5 corresponding to the Nth data line 4 and the active switch 5 corresponding to the (N−1)th data line 4 are disposed in a back-to-back manner; the active switch 5 corresponding to the Nth data line 4 and the active switch 5 corresponding to the (N+1 )th data line 4 are disposed in a face-to-face manner; a distance between the Nth data line 4 and the (N−1)th data line 4 is shorter than a distance between the Nth data line 4 and the (N+1 )th data line 4, corresponding two adjacent data lines 4 are disposed close to each other. On the second substrate 200, the pixel arrangement manner of RGB strip is adopted, the black matrix 6 covers positions corresponding to the scanning lines 3 and the data lines 4 on the color filter film layer, and the description above is equivalent to two adjacent data lines 4 sharing the common light shading portion (e.g., light shading bar as illustrated) in the vertical direction and two adjacent scanning lines 3 sharing the common light shading portion (e.g., light shading bar as illustrated) in the horizontal direction. As a result, it can decrease the coverage area of the light shading layer on the second substrate 200 efficiently, increase the area of the transparent regions and thereby increase the aperture ratio.

In this situation, the area of the transparent regions is about four times of an area of the transparent regions when the active switches 5 are disposed evenly in directions of the scanning lines 3 and the data lines 4.

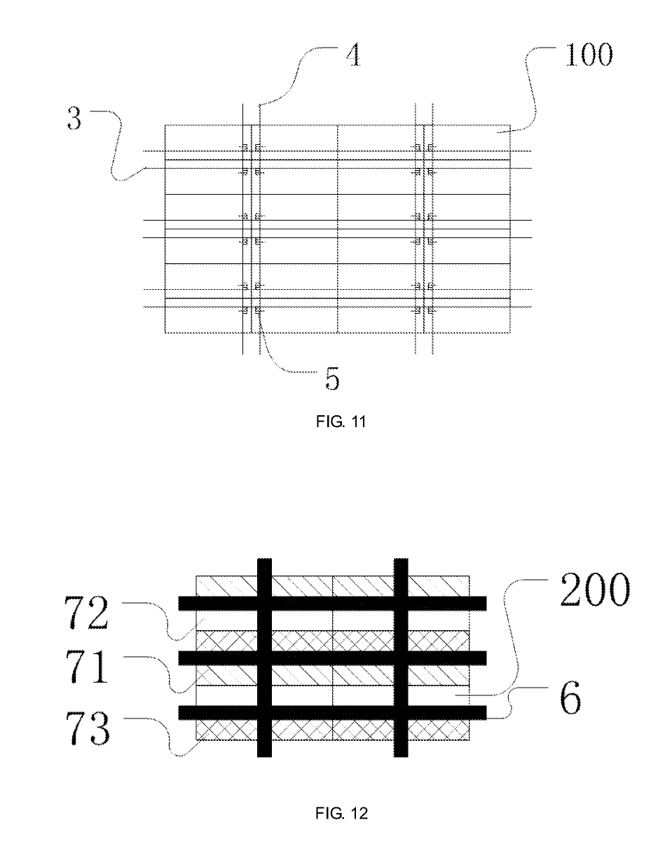

Specifically, FIGS. 11 and 12 show structural schematic views of the display panel according to an embodiment of the disclosure. On the first substrate 100, along a vertical data line 4 direction, the active switch 5 corresponding to the Nth scanning line 3 and the active switch 5 corresponding to the (N−1)th scanning line 3 are adjacent. The active switch 5 corresponding to the Nth scanning line 3 and the active switch 5 corresponding to the (N−1)th scanning line 3 are disposed in a back-to-back manner; the active switch 5 corresponding to the Nth scanning line 3 and the active switch 5 corresponding to the (N+1 )th scanning line 3 are disposed in a face-to-face manner; a distance between the Nth scanning line 3 and the (N−1)th scanning line 3 is shorter than a distance between the Nth scanning line 3 and the (N+1 )th scanning line 3, and corresponding two adjacent scanning lines 3 are disposed close to each other. Along a horizontal scanning line 3 direction, the active switch 5 corresponding to the Nth data line 4 and the active switch 5 corresponding to the (N−1)th data line 4 are adjacent. The active switch 5 corresponding to the Nth data line 4 and the active switch 5 corresponding to the (N−1)th data line 4 are disposed in a back-to-back manner; the active switch 5 corresponding to the Nth data line 4 and the active switch 5 corresponding to the (N+1 )th data line 4 are disposed in a face-to-face manner; a distance between the Nth data line 4 and the (N−1)th data line 4 is shorter than a distance between the Nth data line 4 and the (N+1 )th data line 4, and corresponding two adjacent data lines 4 are disposed close to each other. On the second substrate 200, the pixel arrangement manner of tri-gate is adopted, the black matrix 6 covers positions corresponding to the scanning lines 3 and the data lines 4 on the color filter film layer, and the description above is equivalent to two adjacent data lines 4 sharing the common light shading portion (e.g., light shading bar as illustrated) in the vertical direction and two adjacent scanning lines 3 sharing the common light shading portion (e.g., light shading bar as illustrated) in the horizontal direction. Consequently, it can decrease the coverage area of the light shading material on the second substrate 200 efficiently, increase the area of the transparent regions and thereby increase the aperture ratio.

In this situation, the area of the transparent regions is about four times of an area of the transparent regions when the active switches 5 are disposed evenly in directions of the scanning lines 3 and the data lines 4.

As further still another embodiment of the disclosure, a backlight module and a display panel of a display device are provided. The specific structure and connecting relationship of the display panel can be referred to FIG. 1 to FIG. 12, so that the specific structure and connecting relationship of the display panel will not be repeated.

In various embodiments, the display panel can be a LCD (liquid crystal display) panel, an OLED (organic light emitting diode) panel, a QLED (quantum dot light emitting diode) panel, a curved display panel or other display panel.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A display panel, comprising
a first substrate, and
a second substrate;
wherein the first substrate comprises a plurality of active switches and conductive wires coupled with the plurality of active switches; and in a same direction, the active switch corresponding to an Nth conductive wire and the active switch corresponding to an (N−1)th conductive wire are adjacent, and the active switch corresponding to the Nth conductive wire and the active switch corresponding to the (N−1)th conductive wire are disposed in a back-to-back manner, and the active switch corresponding to the Nth conductive wire and the active switch corresponding to an (N+1 )th conductive wire are disposed in a face-to-face manner; a distance between the Nth conductive wire and the (N−1)th conductive wire is shorter than a distance between the Nth conductive wire and the (N+1 )th conductive wire;
wherein the second substrate comprises a light shading layer at positions corresponding to the Nth conductive wire and the (N−1)th conductive wire;
wherein the conductive wires comprise scanning lines coupled with a gate driver of the display panel and data lines coupled with a source driver of the display panel;
wherein the display panel further comprises pixel units corresponding to the active switches; and the light shading layer crisscrosses along directions of the scanning lines and the data lines to thereby form a plurality of transparent regions, and each of the transparent regions corresponds to four pixel units, and each of the four pixel units comprises a red pixel unit, a green pixel unit and a blue pixel unit, and the red pixel unit, the green pixel unit and the blue pixel unit are sequentially arranged along a direction of the conductive wires with same directions.

2. A display panel, comprising
a first substrate, and
a second substrate;
wherein the first substrate comprises a plurality of active switches and conductive wires coupled with the plurality of active switches; and in a same direction, the active switch corresponding to an Nth conductive wire and the active switch corresponding to an (N−1)th conductive wire are adjacent, and the active switch corresponding to the Nth conductive wire and the active switch corresponding to the (N−1)th conductive wire are disposed in a back-to-back manner, and the active switch corresponding to the Nth conductive wire and the active switch corresponding to an (N+1 )th conductive wire are disposed in a face-to-face manner; a distance between the Nth conductive wire and the (N−1)th conductive wire is shorter than a distance between the Nth conductive wire and the (N+1 )th conductive wire;
wherein the second substrate comprises a light shading layer at positions corresponding to the Nth conductive wire and the (N−1)th conductive wire.

3. The display panel according to claim 2, wherein the conductive wires comprise scanning lines coupled with a gate driver of the display panel.

4. The display panel according to claim 3, wherein the display panel further comprises pixel units corresponding to the active switches; the light shading layer forms a plurality of transparent regions along the scanning lines and their intersecting directions, each of the transparent regions corresponds to two pixel units.

5. The display panel according to claim 2, wherein the conductive wires comprise data lines coupled with a source driver of the display panel.

6. The display panel according to claim 5, wherein the display panel further comprises pixel units corresponding to the active switches; the light shading layer forms a plurality of transparent regions along the data lines and their intersecting direction, each of the transparent regions corresponds to two pixel units.

7. The display panel according to claim 2, wherein the conductive wires comprise scanning lines coupled with a gate driver of the display panel and data lines coupled with a source driver of the display panel.

8. The display panel according to claim 7, wherein the display panel further comprises pixel units corresponding to the active switches; and the light shading layer crisscrosses along directions of the scanning lines and the data lines to thereby form a plurality of transparent regions, each of the transparent regions corresponds to four pixel units.

9. The display panel according to claim 2, wherein the display panel further comprises pixel units corresponding to the active switches, and the pixel units comprise a red pixel unit, a green pixel unit and a blue pixel unit, and the red pixel unit, the green pixel unit and the blue pixel unit are arranged in sequence along a direction of the conductive wires with same directions.

10. The display panel according to claim 2, wherein the light shading layer adopts a black matrix.

11. A display device, the display device comprising a backlight module and a display panel, the display panel comprising
a first substrate, and
a second substrate;
wherein the first substrate comprises a plurality of active switches and conductive wires coupled with the plurality of active switches; and in a same direction, the active switch corresponding to an Nth conductive wire and the active switches corresponding to an (N−1)th conductive wire are adjacent, and the active switch corresponding to the Nth conductive wire and the active switches corresponding to the (N−1)th conductive wire are disposed in a back-to-back manner, and the active switch corresponding to the Nth conductive wire and the active switch corresponding to an (N+1 )th conductive wire are disposed in a face-to-face manner; a distance between the Nth conductive wire and the (N−1)th conductive wire is shorter than a distance between the Nth conductive wire and the (N+1 )th conductive wire;
wherein the second substrate comprises a light shading layer at positions corresponding to the Nth conductive wire and the (N−1)th conductive wire.

12. The display device according to claim 11, wherein the conductive wires comprise scanning lines coupled with a gate driver of the display panel.

13. The display device according to claim 12, wherein display panel further comprises pixel units corresponding to the active switches; the light shading layer forms a plurality of transparent regions along the scanning lines and their intersecting directions, each of the transparent regions corresponds to two pixel units.

14. The display device according to claim 11, wherein the conductive wires comprise data lines coupled with a source driver of the display panel.

15. The display device according to claim 14, wherein the display panel further comprises pixel units corresponding to the active switches; the light shading layer forms a plurality of transparent regions along the data lines and their intersecting directions, each of the transparent regions corresponds to two pixel units.

16. The display device according to claim 11, wherein the conductive wires comprise scanning lines coupled with a gate driver of the display panel and data lines coupled with a source driver of the display panel.

17. The display device according to claim 16, wherein the display panel further comprises pixel units corresponding to the active switches; and the light shading layer crisscrosses along directions of the scanning lines and the data lines to thereby form a plurality of transparent regions, each of the transparent regions corresponds to four pixel units.

18. The display device according to claim 11, wherein the display panel further comprises pixel units corresponding to the active switches, and the pixel units comprise a red pixel unit, a green pixel unit and a blue pixel unit, and the red pixel unit, the green pixel unit and the blue pixel unit are sequentially arranged along a direction of the conductive wires with same directions.

19. The display device according to claim 11, wherein the light shading layer has a black matrix.
